(19) United States
(12) Patent Application Publication
(10) Pub. No.: US 2013/0302934 A1
(43) Pub. Date: Nov. 14, 2013

(54) METHOD OF MANUFACTURING CAPACITIVE ELECTROMECHANICAL TRANSDUCER

(71) Applicants: Ayako Kato, Kawasaki-shi (JP); Kazutoshi Torashima, Yokohama-shi (JP); Yasuhiro Soeda, Yokohama-shi (JP); Shinichiro Watanabe, Kawasaki-shi (JP)

(72) Inventors: Ayako Kato, Kawasaki-shi (JP); Kazutoshi Torashima, Yokohama-shi (JP); Yasuhiro Soeda, Yokohama-shi (JP); Shinichiro Watanabe, Kawasaki-shi (JP)

(73) Assignee: CANON KABUSHIKI KAISHA, Tokyo (JP)

(21) Appl. No.: 13/981,504

(22) PCT Filed: Jan. 24, 2012
(86) PCT No.: PCT/JP2012/051903

§ 371 Date: Jul. 24, 2013

(30) Foreign Application Priority Data
Feb. 11, 2011 (JP) 2011-027966

(51) Int. Cl. H01L 41/33

(52) U.S. Cl. CPC H01L 41/33
USPC 438/53

(57) ABSTRACT

Provided is a method of manufacturing a capacitive electromechanical transducer using fusion bonding, which is capable of reducing fluctuations in initial deformation among diaphragms caused at positions having different boundary conditions such as the bonding area, thereby enhancing the uniformity of the transducer and stabilizing the sensitivity and the like. The method of manufacturing a capacitive electromechanical transducer includes: forming an insulating layer on a first silicon substrate and forming at least one recess; fusion bonding a second silicon substrate onto the insulating layer; and thinning the second silicon substrate and forming a silicon film. The method further includes, before the bonding of the second silicon substrate onto the insulating layer, forming a groove in the insulating layer at the periphery of the at least one recess.

### TECHNICAL FIELD

The present invention relates to a method of manufacturing a capacitive electromechanical transducer to be used as an ultrasound transducer or the like.

### BACKGROUND ART

Conventionally, micromechanical members to be manufactured using micromachining technology can be processed on the order of micrometers, and various functional microelements are materialized using such micromechanical members. A capacitive transducer using such technology (capacitive micromachined ultrasonic transducer (CMUT)) is being researched as an alternative to a piezoelectric element. With such a CMUT, ultrasound may be transmitted and received using vibrations of a diaphragm, and in particular, excellent broadband characteristics in a liquid may be obtained with ease. An example of the transducer is a capacitive electromechanical transducer that uses a monocrystalline silicon diaphragm formed on a silicon substrate by bonding or other methods (see Patent Literature 1). Patent Literature 1 discloses a capacitive electromechanical transducer manufactured by fusion bonding a monocrystalline silicon film onto a silicon substrate, exposing the monocrystalline silicon film after the bonding, and forming a cell having the fusion-bonded film.

Patent Literature 2 discloses a capacitive electromechanical transducer in which a signal blocking part for blocking transmission/reception of a signal generated when a diaphragm displaces or vibrates is provided outside of cells at the outermost periphery or the end of the capacitive electromechanical transducer. The disclosed structure of the capacitive electromechanical transducer enables uniform and stable operations of cells.

### CITATION LIST

### Patent Literature

PTL 1: U.S. Pat. No. 6,958,255 B2
PTL 2: WO 2008/136198 A1

### SUMMARY OF INVENTION

### Technical Problem

The capacitive electromechanical transducers can be manufactured by forming the monocrystalline silicon diaphragm on the silicon substrate by a bonding method involving high-temperature processing. In a transducer device (element) constituting the capacitive electromechanical transducer, the bonding area around the cell varies for each cell during the bonding involving high-temperature processing, with the result that the amount of deformation of the diaphragm may vary for each cell (fluctuations in diaphragm deformation amount). The fluctuations are considered to be caused by the difference in thermal expansion coefficient between the diaphragm and an insulating layer, the difference in residual amount of moisture or gas generated when the high-temperature processing is performed, and the warp of the substrate due to internal stress in the diaphragm and the insulating layer. The fluctuations in diaphragm deformation amount for each cell lead to fluctuations in transmission efficiency and detection sensitivity of ultrasound. However, the above-mentioned technology of Patent Literature 2 is not aimed at reducing the fluctuations. In order to solve the problems described above, the present invention has an object of providing a method of manufacturing a capacitive electromechanical transducer, which is capable of reducing the fluctuations in diaphragm deformation amount among cells constituting the device and thereby reducing the fluctuations in transmission efficiency and detection sensitivity.

### Solution to Problem

In view of the above-mentioned problems, a method of manufacturing a capacitive electromechanical transducer according to the present invention includes the following steps. Specifically, the method includes: forming an insulating layer on a first silicon substrate, and forming at least one recess in the insulating layer; fusion bonding a second silicon substrate onto the insulating layer; and thinning the second silicon substrate, and forming a silicon film. The method further includes, before the fusion bonding of the second silicon substrate onto the insulating layer, forming a groove in the insulating layer at a periphery of the at least one recess.

### Advantageous Effects of Invention

According to the method of manufacturing a capacitive electromechanical transducer of the present invention, before the first silicon substrate and the second silicon substrate are fusion bonded, the groove is formed at the periphery of the recess (which becomes a gap) provided in the insulating layer on the first silicon substrate. The groove is present when the fusion bonding is performed. Thus, the fluctuations in initial deformation among the diaphragms of the cells within the device can be reduced, and hence the fluctuations in detection sensitivity and transmission efficiency of the transducer can be reduced.

Preferred embodiments of the present invention will now be described in detail in accordance with the accompanying drawings.

### BRIEF DESCRIPTION OF DRAWINGS

FIGS. 1A, 1B, 1C, 1D, 1E, 1F, and 1G are views of the cross section taken along the line X-X of FIG. 2, illustrating a method of manufacturing a capacitive electromechanical transducer according to an embodiment or Example 1 of the present invention.

FIG. 2 is a top view illustrating the capacitive electromechanical transducer according to the embodiment or Example 1.

FIG. 3 is a view illustrating the cross section taken along the line Y-Y of FIG. 2.

FIG. 4 is a top view illustrating the capacitive electromechanical transducer according to Example 2 of the present invention.

FIG. 5 is a view illustrating the cross section taken along the line W-W of FIG. 4.

FIG. 6A is a cross-sectional view illustrating the manufacturing method according to Example 2 of the present invention.

FIG. 6B is a cross-sectional view illustrating a manufacturing method according to Example 3 of the present invention.

FIGS. 7A and 7B are graphs showing the effects of eliminating fluctuations in diaphragm deformation amount obtained by the manufacturing method according to the present invention.

FIG. 8 is a top view of an example of an electromechanical transducer manufactured by the manufacturing method according to the present invention.

FIG. 9 is a top view of an example of a device of the electromechanical transducer manufactured by the manufacturing method according to the present invention.

### DESCRIPTION OF EMBODIMENTS

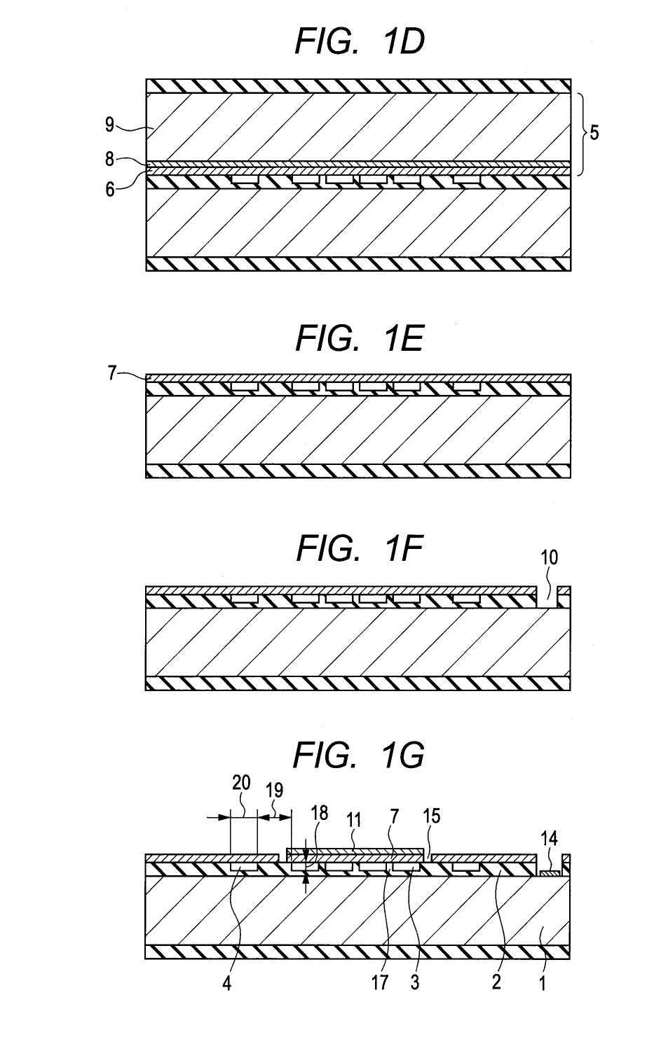

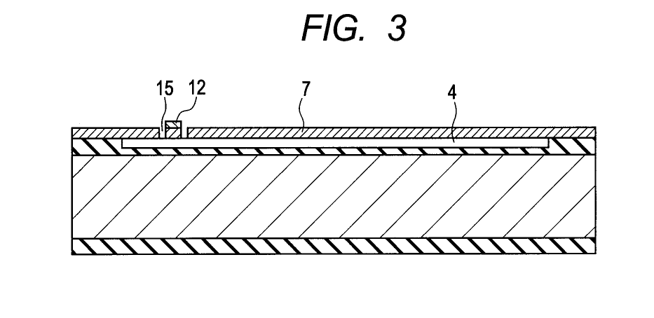

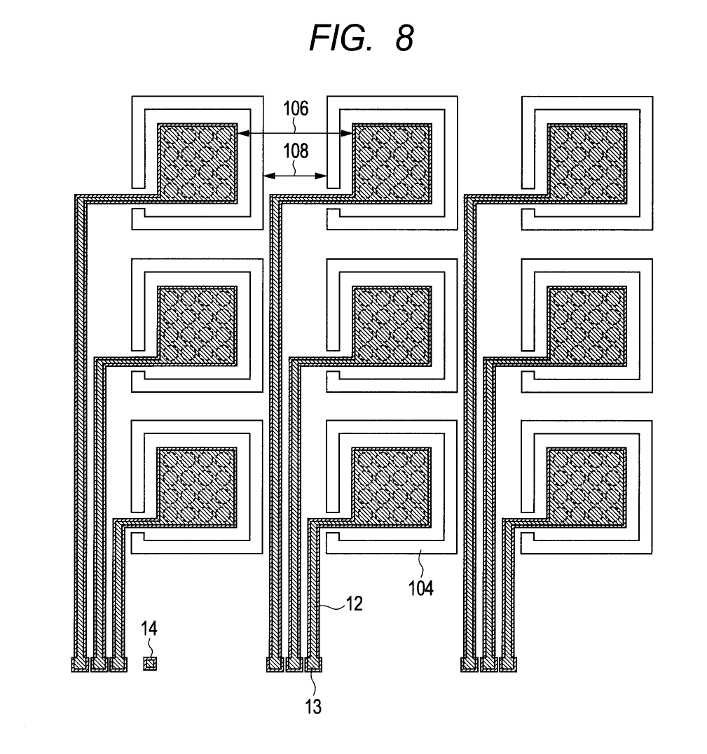

The feature of the present invention resides in that, before the step of fusion bonding a second silicon substrate on an insulating layer which is formed on a first silicon substrate and which has at least one recess, the step of forming a groove in the insulating layer at the periphery of the at least one recess is performed. In this basic configuration, a method of manufacturing a capacitive electromechanical transducer of the present invention may employ various forms. Typically, the at least one recess and the groove are electrically separated from each other by forming on the diaphragm a separating groove which is closed so as to surround the periphery of the recess (such as in the example of FIG. 2) or by preventing a silicon film from being present above the groove (such as in the example of FIG. 8). The step of forming the at least one recess and the step of forming the groove can be performed together in the same step (see Example 2 to be described later). The groove may be a continuous closed loop groove (in the example of FIG. 2) and may be a groove having a shape with a starting point and an end point, in which the insulating layer remains between the two points so as to separate the two points (such as in the example of FIG. 4). In the case of the loop groove, as illustrated in FIG. 2 and other figures, electrical wiring connected to an electrode above the recess can be formed so as to cross the loop groove. In the case of the groove having the starting point and the end point, as illustrated in FIG. 4 and other figures, electrical wiring connected to the electrode above the recess can be formed above the insulating layer between the starting point and the end point of the groove. The groove or the loop groove may be formed around the at least one recess so as to enclose the at least one recess only once as illustrated in FIGS. 2 and 8, or may be formed around the at least one recess so as to enclose the at least one recess multiple times in parallel (“in parallel” means being arranged towards the same direction and refers to a literally parallel state and also a non-parallel state) as illustrated in FIG. 4 and other drawings. The groove may be formed around the recess in any manner as long as the boundary conditions, such as the bonding area of each cell, can be made substantially uniform to thereby reduce fluctuations in initial deformation among the diaphragms of the cells due to thermal stress generated when the second silicon substrate is fusion bonded onto the first silicon substrate having the groove.

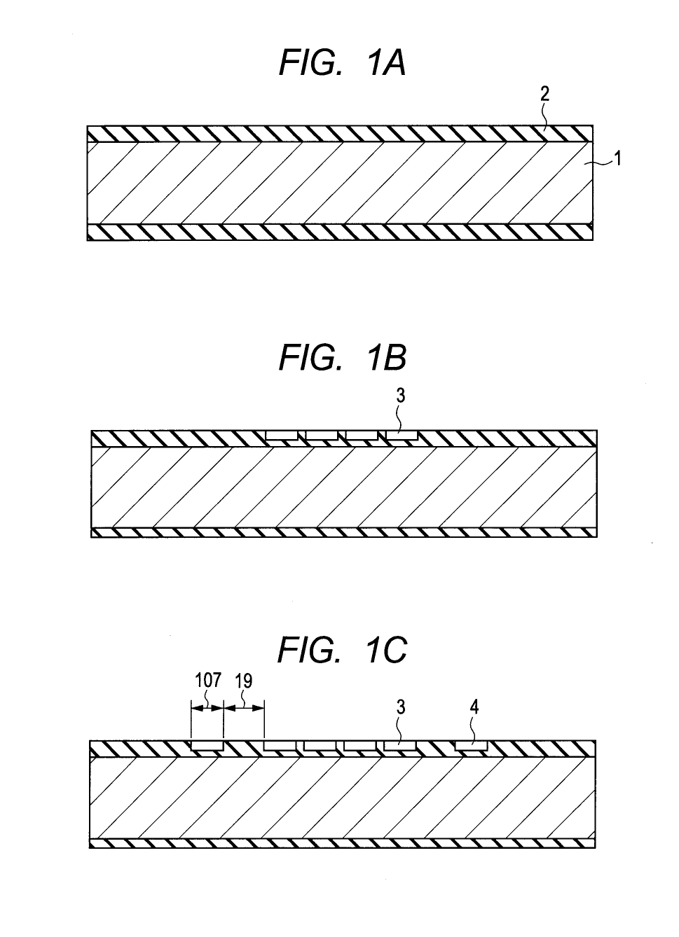

Hereinafter, an embodiment of the method of manufacturing a capacitive electromechanical transducer according to the present invention is described with reference to FIGS. 1A to 1G, 2, and 3. In the capacitive electromechanical transducer, as illustrated in FIG. 2, multiple devices (elements) 101 each including multiple cellular structures 102 are arranged in an array. Although only six devices are illustrated in FIG. 2, the number of the devices is not limited thereto. Similarly, although the illustrated device 101 is formed of sixteen cellular structures 102, the number of the cellular structures is not limited thereto. Also, although the planar shape of cells is circular in this embodiment, it may be quadrangular, hexagonal, or other shapes. Arbitrary arrangement positions of the cells and the devices can be adopted.

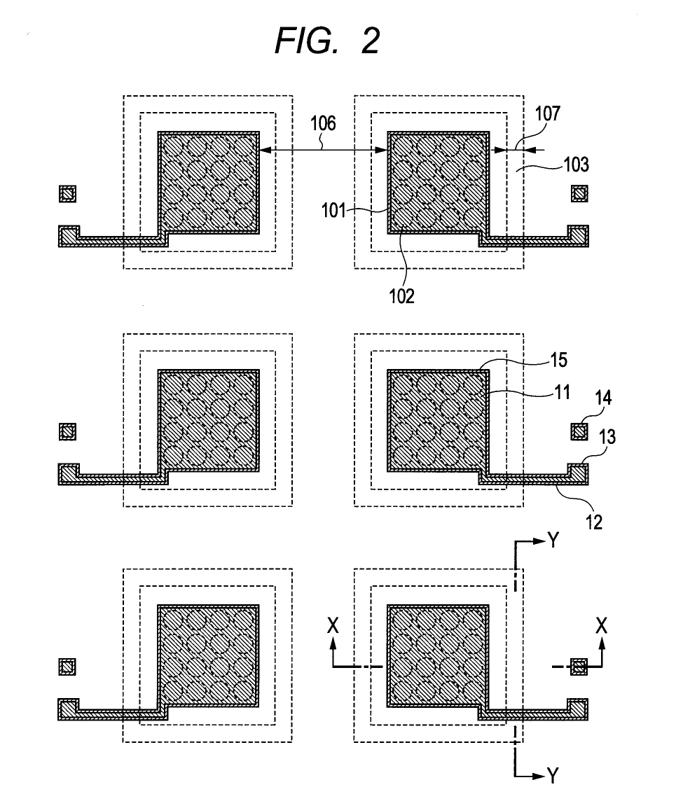

Referring to FIG. 1G illustrating the cross section of the line X-X of FIG. 2 and FIG. 3 illustrating the cross section of the line Y-Y of FIG. 2, the cellular structure 102 includes a monocrystalline silicon diaphragm 7, a gap (recess) 3 as a void, a diaphragm supporting portion 17 for supporting the diaphragm 7, and a silicon substrate 1. A monocrystalline silicon diaphragm has almost no residual stress, small fluctuations in thickness, and small fluctuations in spring constant as a diaphragm, as compared to a laminated diaphragm (such as silicon nitride film), and hence it can reduce fluctuations in performance among the devices and the cellular structures. It is desired to use an insulator as the diaphragm supporting portion 17, such as silicon oxide and silicon nitride. Otherwise, it is necessary to form an insulating layer on the first silicon substrate 1 in order to insulate the first silicon substrate 1 and the monocrystalline silicon diaphragm 7 from each other. The first silicon substrate 1 is used as a common electrode for the devices in this embodiment. It is therefore desired that the first silicon substrate 1 be a low resistance substrate for promoting ohmic behavior. It is desired that the resistivity be 0.1 Ωcm or lower. The “ohmic” means that the resistance value is constant irrespective of the direction of current and the magnitude of voltage.

The monocrystalline silicon diaphragm 7 has a separating groove 15 formed therein, and concurrently it can be used as a signal extraction electrode for extracting a signal for each device. In order to improve the conductive characteristics of the first silicon substrate 1 and the monocrystalline silicon diaphragm 7, a thin metal film such as aluminum may be formed on the first silicon substrate 1 and the monocrystalline silicon diaphragm 7. The monocrystalline silicon diaphragm 7 is used as the signal extraction electrode. It is therefore desired that the monocrystalline silicon diaphragm 7 also have low resistance. It is desired that the resistivity be 0.1 Ωcm or lower.

The device 101 has, in its periphery, a groove 103 (represented by 4 in FIGS. 1C to 1G and 3; a closed loop groove in this embodiment) which is formed in the same insulating layer as a layer of an insulating film supporting portion. As illustrated in FIG. 2, the groove 103 is disposed as a single loop groove which is closed so as to surround the periphery of the device 101 completely. With the loop groove 103 provided, the boundary conditions, such as the bonding area of each cellular structure, can be made substantially uniform to thereby reduce fluctuations in amount of deformation among the diaphragms 7 due to thermal stress generated in fusion bonding or the like. At the periphery of the device 101, the monocrystalline silicon diaphragm 7 and a monocrystalline silicon film formed above the loop groove 103 are electrically separated from each other, to thereby electrically separate the device and the loop groove from each other. In the driving of the device 101, if the device 101 is not electrically insulated from the loop groove 103, the monocrystalline silicon film present above the loop groove may be driven simultaneously and noise is generated. Thus, the separating groove 15 for electrically separating the recess and an inner edge portion of the loop groove is formed between the device and the loop groove, to thereby reduce the noise. The inner edge portion of the loop groove means one end surface of a region 20 (see FIG. 1G) in which the loop groove is provided, the one end surface being closer to the recess of the gap 3. In FIG. 2, the separating groove 15 serves as the electrical separation between the recess and the loop groove and the formation of the signal extraction electrode. The above-mentioned configuration can enhance the uniformity of the device and the device array, thereby stabilizing receiving sensitivity and the like.

The drive principle of this embodiment is as follows. In the case of receiving ultrasound by a capacitive electromechanical transducer, a direct voltage is kept applied to the monocrystalline silicon diaphragm 7 by a voltage applying unit (not shown). When ultrasound is received, the diaphragm 7 is deformed, and a distance (see FIG. 1G), specifically the distance between the monocrystalline silicon diaphragm 7 (signal extraction electrode) and the first silicon substrate 1 (common electrode), varies to change the capacitance. This change in capacitance causes a current to flow through the diaphragm 7. This current is converted into a voltage by a current-to-voltage converter (not shown), which is then output as a reception signal of ultrasound. Further, a direct voltage and an alternating voltage are applied to the monocrystalline silicon diaphragm 7 so that the diaphragm 7 may be vibrated by electrostatic force. In this way, ultrasound can be transmitted.

Referring to FIGS. 1A to 1G, the method of manufacturing a capacitive electromechanical transducer according to this embodiment is described. As illustrated in FIG. 1A, an insulating layer (insulating film) 2 is formed on the first silicon substrate 1. The first silicon substrate 1 is a low resistance substrate, and it is preferred that the resistivity be 0.1 Ωcm or lower. The insulating layer 2 is silicon oxide, silicon nitride, or the like. The insulating layer 2 can be formed by chemical vapor deposition (CVD), thermal oxidation, or the like.

Next, as illustrated in FIG. 1B, the recess 3 to become a gap is formed. The recess 3 can be formed by dry etching, wet etching, or the like. The recess 3 corresponds to the dielectric of a capacitor. Next, as illustrated in FIG. 1C, a loop groove 4 is formed. The loop groove 4 can be formed by dry etching, wet etching, or the like. The loop groove 4 can be provided at the outermost periphery of at least one recess 3. It is preferred to dispose the groove at locations where the distance between cells or the distance between devices is non-uniform and the boundary conditions such as the bonding area are different.

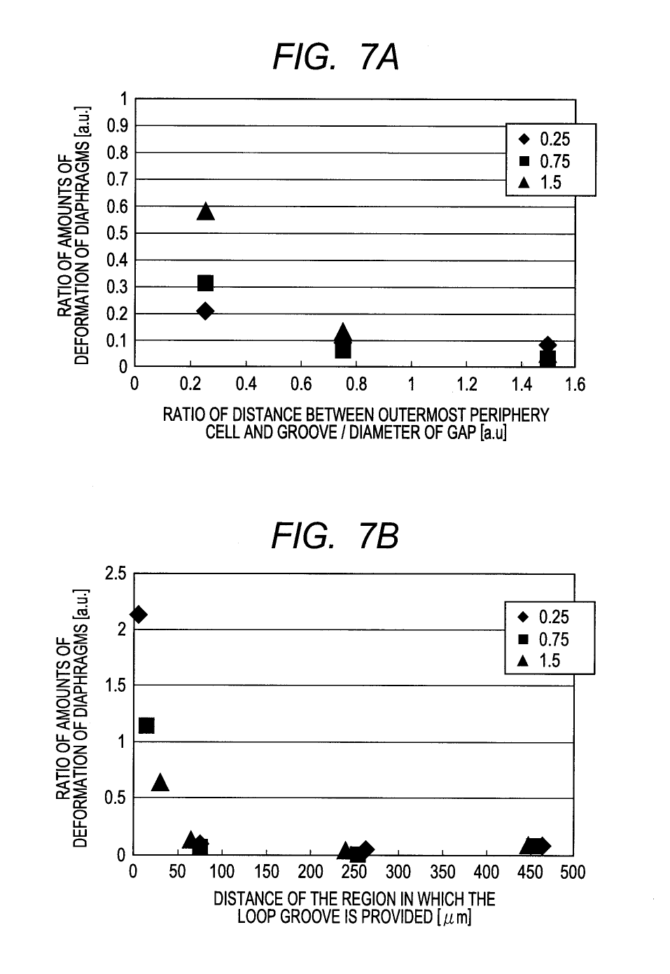

Referring to FIGS. 7A and 7B, the effects obtained by providing at least one groove such as the loop groove 4 are described. FIG. 7A shows the relation between the fluctuations in diaphragm deformation amount and the distance between the cell at the outermost periphery and the groove. FIG. 7B shows the relation between the fluctuations in diaphragm deformation amount and the region in which the groove is provided. The horizontal axis of FIG. 7A represents the ratio of a distance 19 between the cell at the outermost periphery and the groove with respect to the diameter of the recess 3. The vertical axis of FIG. 7A represents an absolute value of the difference between the amount of deformation of the diaphragm in the cell at the outermost periphery and the amount of the deformation of the diaphragm in the cell at the center portion in the case where the groove is provided, in the form of the ratio with respect to an absolute value of the amount of deformation of the diaphragm in the cell at the center portion. A larger ratio of the vertical axis indicates larger fluctuations in transmitting or receiving sensitivity. In other words, if an electromechanical transducer has near 0 amount of the above-mentioned absolute value of the difference in diaphragm deformations, the performance uniformity within the device or among the devices is higher, and the receiving sensitivity and the like can be stabilized. FIG. 7A shows the case where the region 20 in which the groove is provided is 100 μm. The series in the graph indicate the difference in groove width 107 (see FIG. 2), and the figure such as 0.25 indicates the ratio of the groove width 107 with respect to the diameter of the recess 3. For example, in the case where the diameter of the recess 3 is 35 μm, the groove width for the series 0.25 is 8.75 μm, the groove width for the series 0.75 is 26.25 μm, and the groove width for the series 1.5 is 52.5 μm. Depending on the difference in groove width, the number of loops of the groove (the number of grooves) to be provided in the region 20 varies. As shown in FIG. 7A, even when the number of grooves is different, the fluctuations in diaphragm deformation amount are reduced by increasing the distance between the cell at the outermost periphery and the groove.

Referring to FIG. 7A, when the ratio of the distance 19 between the cell at the outermost periphery and the groove with respect to the diameter of the recess 3 is 0.5 or more, the above-mentioned difference in diaphragm deformation amount is substantially 0. It is therefore preferred that the ratio of the distance 19 between the cell at the outermost periphery and the groove with respect to the diameter of the recess 3 be 0.5 or more. The monocrystalline silicon film formed above the groove is more likely to be deformed than the diaphragm of the cell, and hence, if the groove is too close to the recess 3, the deformation of the monocrystalline silicon film formed above the groove affects the diaphragm 7 of the cell to increase the amount of deformation of the diaphragm 7. On the other hand, when the above-mentioned ratio increases, that is, the state is closer to the state in which no groove is provided, the boundary conditions such as the bonding area become non-uniform, and the above-mentioned difference in diaphragm deformation amount increases. It is therefore preferred that the ratio of the distance 19 between the cell at the outermost periphery and the groove with respect to the diameter of the recess 3 be in the range of from about 0.5 to about 2.0.

The horizontal axis of FIG. 7B represents the distance of the region 20 in which the loop groove is provided, and the vertical axis thereof represents the same as in FIG. 7A. The series of the graph are also the same as in FIG. 7A. FIG. 7B shows the case where the ratio of the distance 19 between the outermost gap end surface and the groove end surface with respect to the diameter of the recess 3 is 0.75. Referring to FIG. 7B, when the region 20 in which the groove is provided is 50 μm or more, the above-mentioned difference in diaphragm deformation amount is substantially 0. It is therefore preferred that the region 20 in which the loop groove is provided be 50 μm or more because it is possible to significantly reduce the fluctuations in receiving sensitivity and transmission efficiency. Although the number of loops of the groove (the number of grooves) varies depending on the difference in series such as 0.25, the groove only needs to be provided in the region 20 so as to enclose the device at least once. FIG. 7B shows the case where the ratio is 0.75, but, even when the ratio is other than 0.75, the fluctuations in diaphragm deformation amount are similarly reduced by increasing the distance of the region 20 in which the groove is provided.

The fluctuations in diaphragm deformation amount can be reduced also by providing a structure equivalent to the cellular structure around the device. This method, however, needs a larger region than providing a groove typified by the above-mentioned loop groove, in order to sufficiently reduce the fluctuations in amount of deformation. Therefore, in the case of a capacitive electromechanical transducer in which the devices are arranged in an array as illustrated in FIG. 8 to be described later, the structure equivalent to the cellular structure formed around the device may hinder the extraction of lead-out wiring. On the other hand, in the case of the loop groove as in this embodiment, the amounts of deformation of the diaphragms can be made substantially uniform by disposing the loop groove in a narrower region than the structure equivalent to the cellular structure. Therefore, even when an arrangement interval 106 of the devices is small, the wiring can be led out.

The depth of the groove 4 (the groove 103 of FIG. 2) may be set to a desired depth, but it is preferred to set the groove to such a depth that the insulating layer 2 remains at the bottom portion of the groove 4. With the insulating layer 2 remaining at the bottom portion of the groove 4, the exposure of the first silicon substrate 1 can be prevented when the monocrystalline silicon film above the groove is removed. By preventing the exposure of the first silicon substrate 1, it is possible to prevent short-circuit between an electrode 11 and the first silicon substrate 1, which is otherwise caused when an external conductive substance is adhered between the electrode 11 on the diaphragm 7 and the groove 4. By setting the groove 4 and the recess 3 to have the same depth, it is also possible to form the recess 3 and the groove 4 at the same time. This realizes the reduction in number of photomasks, the reduction in number of manufacturing processes, the prevention of misalignment, and the like (see Example 2 to be described later).

The width 107 of the groove 4 can be set to a desired value. As shown in FIG. 7A, even when the distance 19 between the cell at the outermost periphery and the groove is small, the difference in diaphragm deformation amount can be reduced by providing a narrower groove width 107. In this case, the groove can be formed in the vicinity of the cell at the outermost periphery, and hence a wiring region 108 (see FIG. 8) can be widened so as to extract a larger number of wirings. It is preferred that the width 107 be set so that a monocrystalline silicon film formed above the groove does not contact the bottom portion of the groove. When the groove width is set smaller than the diameter of the recess 3, the monocrystalline silicon film formed above the groove does not contact the bottom portion. It is therefore preferred that the width of the groove be equal to or smaller than the diameter of the recess 3.

In the case where the width 107 of the groove is larger than the diameter of the recess 3, and the amount of deformation of the monocrystalline silicon film above the groove is larger than the amount of deformation of the monocrystalline silicon diaphragm formed above the recess 3, the following problem occurs. If a voltage is applied to the capacitive electromechanical transducer in the state in which an external conductive substance or the like is still adhered between the electrode 11 and the groove 4, the monocrystalline silicon film formed above the groove contacts the first silicon substrate 1 before the monocrystalline silicon diaphragm formed above the recess 3 does. When the application voltage is further increased, breakdown occurs between the monocrystalline silicon film formed above the groove and the first silicon substrate 1, resulting in a fear that the capacitive electromechanical transducer does not work any more. From this viewpoint, it is preferred that the groove width 107 be substantially equal to or smaller than the diameter of the recess 3. Further, if the monocrystalline silicon film above the groove contacts the bottom portion of the groove, the amount of deformation of the monocrystalline silicon diaphragm above the recess 3 may be changed from the design value. It is therefore preferred that the width of the groove be substantially equal to or smaller than the diameter of the recess 3.

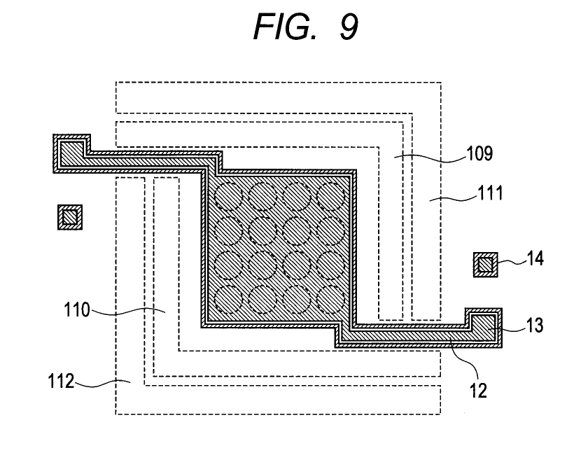

As illustrated in FIG. 9, multiple L-shaped grooves 109, 110, 111, and 112, in each of which the starting point and the end point are located at different positions, may be used so as to enclose the device multiple times. This configuration provides multiple locations where the starting point and the end point are separated from each other, to thereby enable the lead-out of electrical wirings from the multiple locations. It is also possible to remove the silicon film above the groove as illustrated in FIG. 8. This prevents the occurrence of noise in the monocrystalline silicon diaphragm 7 above the recess 3, which is otherwise caused when the silicon film above the groove vibrates. Note that, in the configuration of FIG. 8, the diaphragm is removed in portions excluding the device and the wiring, and in the configuration of FIG. 9, the silicon film is present above the grooves 109, 110, 111, and 112.

The manufacturing method is described again with reference to FIGS. 1A to 1G. Next, as illustrated in FIG. 1D, a second silicon substrate 5 is bonded onto the first silicon substrate 1. The second silicon substrate 5 and the first silicon substrate 1 are fusion bonded. Fusion bonding is a method in which polished silicon substrates or a silicon substrate on which SiO₂ film are overlapped are subjected to heat treatment so that the substrates or the substrate and the film are bonded to each other by intermolecular force. When the surfaces of the substrates or the substrate and the film are overlapped in the atmosphere, OH groups of Si—OH are hydrogen-bonded. In this state, if the temperature is increased to as high as about 600 to 1,000° C., the H₂O molecule is released from the OH groups and bonded with oxygen. In a higher temperature of 1,000° C. or more, oxygen diffuses in the silicon wafer and the Si atoms are bonded with each other. In FIG. 1D, as the second silicon substrate 5, a silicon-on-insulator (SOI) substrate is used. The SOI substrate has a structure in which a silicon oxide layer 8 (buried oxide (BOX) layer) is interposed between a silicon substrate 9 (handle layer) and a surface silicon layer (active layer) 6.

Next, as illustrated in FIG. 1E, the second silicon substrate 5 is thinned, and the monocrystalline silicon diaphragm 7 is formed. It is preferred that the monocrystalline silicon diaphragm have a thickness of several μm or less, and hence the second silicon substrate 5 is thinned by etching, grinding, or chemical mechanical polishing (CMP). By backgrinding or CMP, the second silicon substrate 5 can be ground down to about 2 μm. As illustrated in FIG. 1E, when the SOI substrate is used as the second silicon substrate 5, the thinning of the SOI substrate is performed by removing the handle layer 9 and the buried oxide (BOX) layer 8. The handle layer can be removed by grinding, CMP, or etching. The BOX layer can be removed by etching of an oxide film (dry etching or wet etching using hydrofluoric acid). Wet etching using hydrofluoric acid is more preferred because the use of wet etching using hydrofluoric acid prevents silicon from being etched and hence the fluctuations in thickness of the monocrystalline silicon diaphragm caused by etching can be reduced. The active layer 6 in the SOI substrate, which has small fluctuations in thickness, can reduce the fluctuations in thickness of the monocrystalline silicon diaphragm and reduce the fluctuations in spring constant of the monocrystalline silicon diaphragm. Therefore, the fluctuations in performance of the capacitive electromechanical transducer can be reduced.

Next, electrodes are formed, which are necessary for applying a voltage and extracting a signal in the driving of the electromechanical transducer. The electrodes can be formed anywhere and can have any structure as long as a voltage can be applied between the monocrystalline silicon diaphragm 7 and the first silicon substrate 1. The monocrystalline silicon diaphragm 7 may be used as a common electrode, and the first silicon substrate 1 may be divided so that the divided silicon substrates are each used as a signal extraction electrode. Alternatively, the first silicon substrate 1 may be used as the common electrode, and the monocrystalline silicon diaphragm 7 may be used as the signal extraction electrode.

FIGS. 1F and 1G illustrate the case where the monocrystalline silicon diaphragm 7 is used as the signal extraction electrode and the first silicon substrate 1 is used as the common electrode, and illustrate an example of the manufacturing method in which the wiring of the signal extraction electrode and the electrode pads are formed on the diaphragm side. In FIG. 1F, a contact hole 10 is formed in order to establish conduction of the first silicon substrate 1. In FIG. 1G, the electrode 11, the wiring 12, and the electrode pad are formed. Specifically, as illustrated in FIG. 1G, the separating groove 15 is formed in the monocrystalline silicon diaphragm in order to electrically separate the recess and the groove from each other. The separating groove 15 can be formed by dry etching, wet etching, or the like. The separating groove only has to electrically separate the recess and the groove from each other, and, as described above, the separating groove may be provided in other portions than the monocrystalline silicon film. In this embodiment, the device refers to a region inside the separating groove, specifically, a portion excluding the wiring 12, a first electrode pad 13, and a second electrode pad 14.

Through the application of a voltage between the first electrode pad 13 and the second electrode pad 14, a voltage can be applied to the device, and the device can be driven. According to the above-mentioned manufacturing method, the groove is formed before fusion bonding, and hence the fluctuations in silicon diaphragm can be reduced and the fluctuations in transmission efficiency and detection sensitivity can be reduced. In the above-mentioned manufacturing method, it is also possible to provide grooves so as to enclose the recess multiple times. As illustrated in FIG. 4, it is also possible to further form a second groove 105 so as to surround a first groove 104 surrounding the recess of the device. This configuration can further reduce the fluctuations in deformation of the diaphragms.

In the following, the present invention is described in detail by way of more specific examples.

### Example 1

A method of manufacturing a capacitive electromechanical transducer according to Example 1 is described with reference to FIGS. 1A to 1G and 3. In Example 1, a loop groove is provided so that the difference in diaphragm deformation amount becomes 10 nm or less. The width 107 of the loop groove and the distance 19 between the cell at the outermost periphery and the loop groove are each 45 μm, which is equal to the diameter of the recess 3, and the region 20 in which the loop groove is provided is 45 μm.

First, as illustrated in FIG. 1A, the insulating film 2 is formed on the first silicon substrate 1. The resistivity of the first silicon substrate 1 is 0.01 Ωcm. The insulating layer 2 is silicon oxide formed by thermal oxidation, the thickness of which is 400 nm. Silicon oxide formed by thermal oxidation has a very small surface roughness, and, even if silicon oxide is formed on the first silicon substrate, the roughness is prevented from increasing from the surface roughness of the first silicon substrate. The surface roughness Rms is 0.2 nm or less. In fusion bonding is performed, when the surface roughness is large, for example, Rms=0.5 nm or more, the bonding is difficult to achieve, which thus causing a bonding failure. The silicon oxide formed by thermal oxidation does not increase the surface roughness and is less likely to cause a bonding failure. Thus, the manufacturing yields can be improved.

Next, as illustrated in FIG. 1B, the recess 3 is formed. The recess 3 can be formed by wet etching. The depth of the recess 3 (distance 18) is 200 nm, and the diameter thereof is 45 μm. An arrangement interval of the recesses 3 is 50 μm, and the recesses 3 are formed in 4 rows and 4 columns as illustrated in FIG. 2. The recess 3 corresponds to the dielectric of a capacitor.

Next, as illustrated in FIG. 1C, the loop groove 4 is formed. The loop groove 4 can be formed by wet etching. The depth of the loop groove is 200 nm. The horizontal width 107 of the loop groove is 45 μm, which is the same as the diameter of the recess 3. As illustrated in FIG. 2, the loop groove is formed so as to surround the periphery of the recess 3 completely and enclose the recess 3 once. The distance 19 between the cell at the outermost periphery and the loop groove is 45 μm.

Next, as illustrated in FIG. 1D, the second silicon substrate 5 is fusion bonded. The fusion bonding in Example 1 is performed under vacuum conditions, in which the inside of the recess 3 is in an almost vacuum state. As the second silicon substrate 5, a silicon-on-insulator (SOI) substrate is used, and an active layer 6 in the SOI substrate is bonded. The active layer 6 is used as the monocrystalline silicon diaphragm 7. The thickness of the active layer 6 is 1.25 μm, and the thickness fluctuations are within ±5%. The resistivity of the active layer 6 is 0.01 Ωcm. Annealing temperature after the bonding is 1,000° C., and annealing time is 4 hours.

Next, as illustrated in FIG. 1E, the second silicon substrate 5 is thinned, and the monocrystalline silicon diaphragm 7 is formed. As illustrated in FIG. 1E, the thinning of the SOI substrate used as the second silicon substrate is performed by removing a handle layer 8 and a buried oxide (BOX) layer 9. The handle layer 8 is removed by grinding. The BOX layer 9 is removed by wet etching using hydrofluoric acid. The use of wet etching using hydrofluoric acid prevents silicon from being etched, and hence the fluctuations in thickness of the monocrystalline silicon diaphragm 7 caused by etching can be reduced.

Next, as illustrated in FIG. 1F, a contact hole 10 is formed in order to establish conduction of the first silicon substrate 1 from the side on which the diaphragm 7 is formed. First, a part of the diaphragm 7 in a region in which the contact hole is to be formed is removed by dry etching, wet etching, or the like. Next, the insulating layer 2 is removed by dry etching, wet etching, or the like. Then, the first silicon substrate 1 is exposed, and the contact hole 10 can be formed.

Next, as illustrated in FIGS. 1G and 3, the upper electrode 11, the wiring 12, and the electrode pad, which are necessary for applying a voltage to the device 101, are provided. First, in order to improve the conductive characteristics of the first silicon substrate 1 and the monocrystalline silicon diaphragm 7, a metal film having good conductivity is formed on the first silicon substrate 1 and the monocrystalline silicon diaphragm 7. As the metal film, a metal such as Al, Cr, Ti, Au, Pt, and Cu can be used. The metal film to become the electrode 11 is provided to a desired thickness, preferably such a thickness as not to hinder the vibration of the diaphragm 7. It is preferred that the metal film to become the wiring 12 be formed to such a thickness to provide a desired wiring resistance. It is preferred that the metal film to become the electrode pads 13 and 14 be formed to such a thickness as to make electrical conduction. The thicknesses of the metal films may be set to the same value in order to form the metal films by performing single film formation and etching. Alternatively, the metal films may be formed by performing film formation and etching several times in order to vary the thickness. After the metal film is formed, the electrode 11, the wiring 12, the first electrode pad 13, and the second electrode pad 14 are formed by patterning. The wiring 12 and the electrode pads may provided at desired positions.

In Example 1, an Al film is formed to a thickness of 200 nm, and the electrode 11, the wiring 12, the first electrode pad 13, and the second electrode pad 14 are formed by patterning. In FIG. 2, the loop groove 103 is provided so as to surround the periphery of the recess completely, and, as illustrated in FIG. 3, the wiring 12 is formed above the loop groove (represented by 4 in FIG. 3). Alternatively, however, the wiring 12 and the separating groove 15 may be eliminated and the first silicon substrate 1 may be divided so that a signal is extracted from the rear side.

Next, the separating groove 15 is formed in the monocrystalline silicon diaphragm 7. The separating groove can be formed by dry etching. The separating groove 15 electrically insulates the recess 3 and the loop groove 4 from each other. Through the application of a voltage between the first electrode pad 13 and the second electrode pad 14, a voltage can be applied to the device 101.

In the device of the capacitive electromechanical transducer manufactured by the manufacturing method of Example 1, the difference in amount of deformation under atmospheric pressure between the diaphragm of the cell at the outermost periphery and the diaphragm of the cell at the center portion is about 5 nm. Conversely, the device which omits the process of FIG. 1C, that is, which has no groove has the above-mentioned difference in amount of deformation of about 40 nm under atmospheric pressure. As described above, with the groove such as a loop groove provided, the fluctuations in diaphragm deformation amount can be reduced and the fluctuations in detection sensitivity and transmission efficiency can be reduced significantly.

### Example 2

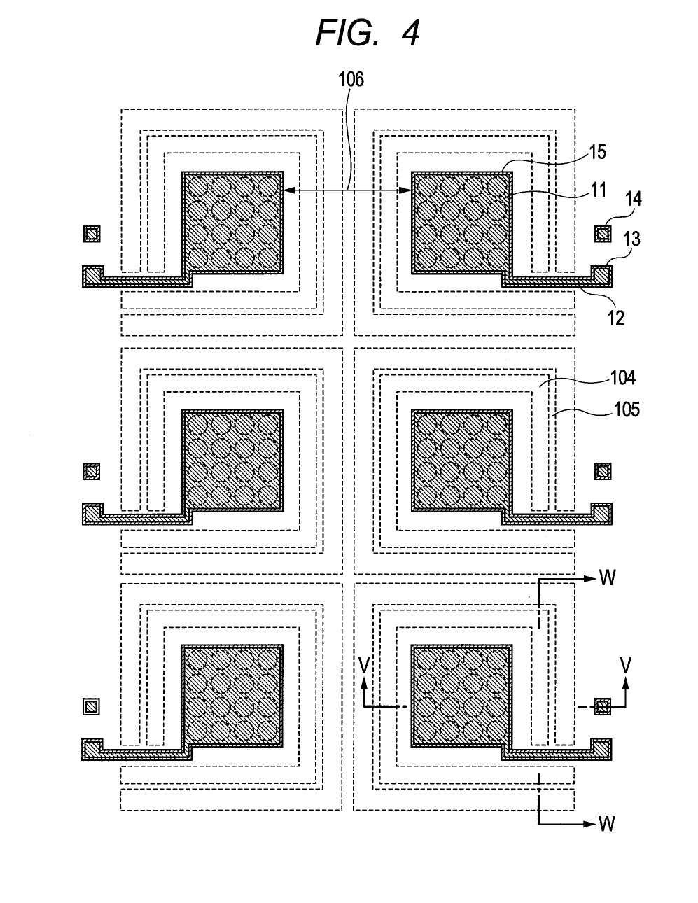

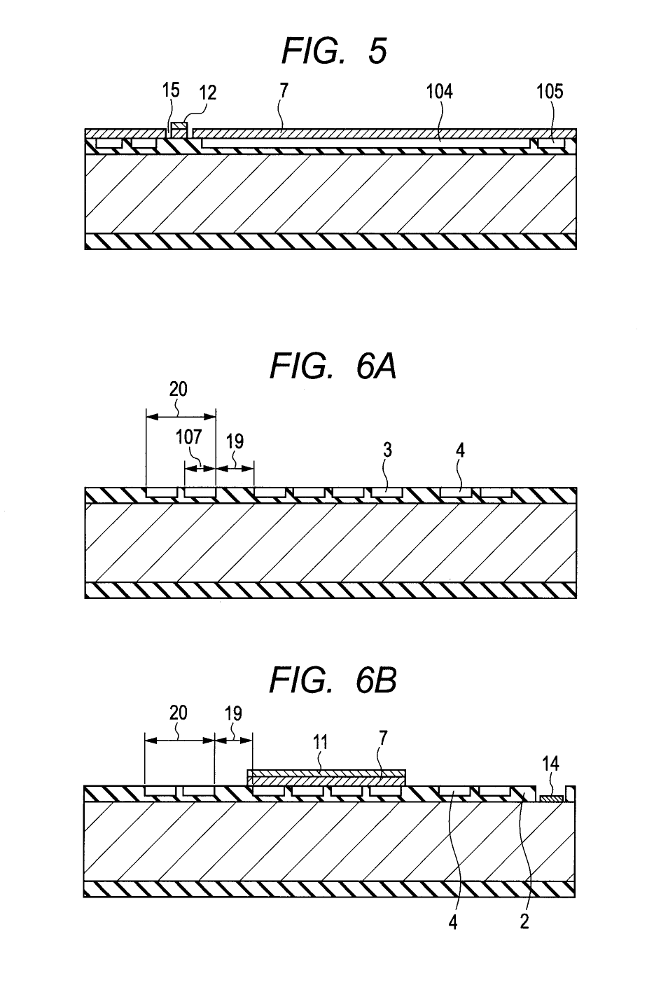

A method of manufacturing a capacitive electromechanical transducer according to Example 2 is described with reference to FIGS. 1A to 1G, 4, 5, and 6A. The manufacturing method of Example 2 is substantially the same as in Example 1. The cross section of the line V-V of FIG. 4 is illustrated in FIG. 1G, and the cross section of the line W-W of FIG. 4 is illustrated in FIG. 5. FIG. 6A is a view illustrating the case where the step of FIG. 1B and the step of FIG. 1C are performed together in the same step. In the manufacturing method of Example 2, based on the above-mentioned graphs of FIGS. 7A and 7B, such a groove as to reduce the difference in diaphragm deformation amount to 2 nm or less is provided.

In Example 2, the width 107 of the groove and the distance 19 between the cell at the outermost periphery and the groove are each 45 μm, which is equal to the diameter of the recess 3, and the region 20 in which the groove is provided is 95 μm. As illustrated in FIG. 6A, the recess 3 and the groove 4 are formed in the same step. The recess 3 and the groove 4 can be formed in the same manner as in FIGS. 1B and 1C of Example 1. This realizes the reduction in number of photomasks required for the manufacture, the reduction in number of manufacturing processes, and the elimination of an alignment error between the formation of the recess and the formation of the groove.

As illustrated in FIG. 4, as the groove, the second groove 104 and the third groove 105 are provided. Each of the second groove 104 and the third groove 105 almost encloses the device but is not closed, that is, each of which is provided so that the starting point and the end point are located at different positions. Here, the almost-enclosing groove is provided so that the interval between the starting point and the end point is 45 μm. Then, as illustrated in FIGS. 1G and 5, the electrode 11, the wiring 12, and the electrode pad, which are necessary for applying a voltage to the device, are provided. As illustrated in FIG. 5, the wiring 12 is provided at a disconnected portion of the groove. In this configuration, no gap is provided under the electrical wiring, and hence the electrical wiring above the groove can be prevented from vibrating during reception of ultrasound. Therefore, the occurrence of noise in the electrical wiring can be prevented. Besides, as compared to the case where the gap is provided under the wiring, the strength of the wiring can also be maintained. In addition, as illustrated in FIG. 9, it is also possible to form multiple grooves such like grooves 109, 110, 111 and 112 illustrated therein, in each of which the starting point and the end point are located at different positions, such as the L-shape grooves. This configuration provides multiple locations where the starting point and the end point are separated from each other, to thereby enable the lead-out of the electrical wiring from multiple locations.

In the device of the capacitive electromechanical transducer manufactured in Example 2, the difference in amount of deformation under atmospheric pressure between the diaphragm of the cell at the outermost periphery and the diaphragm of the cell at the center portion is about 1 nm. On the other hand, the device having no groove has the above-mentioned difference in amount of deformation of about 40 nm. With the above-mentioned groove formed, the fluctuations in diaphragm deformation amount can be reduced more and the fluctuations in detection sensitivity and transmission efficiency can be reduced significantly.

### Example 3

A method of manufacturing a capacitive electromechanical transducer according to Example 3 is described with reference to FIGS. 1A to 1G, 4, 5, and 6B. The method of manufacturing a capacitive electromechanical transducer of Example 3 is substantially the same as in Example 1. The cross section of the line V-V of FIG. 4 is illustrated in FIG. 1G, and the cross section of the line W-W of FIG. 4 is illustrated in FIG. 5. FIG. 6B is a view illustrating the step of removing a monocrystalline silicon film above the groove. Also in Example 3, an almost-enclosing groove equivalent to that in Example 2 is provided.

In the method of manufacturing a capacitive electromechanical transducer of Example 3, as illustrated in FIG. 6B, the monocrystalline silicon film above the groove is removed. The monocrystalline silicon film is removed in the following manner similarly to FIG. 1G. First, an Al film is formed to a thickness of 200 nm, and the electrode 11, the wiring 12, the first electrode pad 13, and the second electrode pad 14 are formed by patterning. Next, silicon is removed by dry etching. This process removes a monocrystalline silicon film excluding a monocrystalline silicon diaphragm provided above the recess, thereby electrically insulating the recess 3 and the groove 4 from each other. By removing the monocrystalline silicon film above the groove, it is possible to prevent the monocrystalline silicon film above the groove from vibrating at the time of reception or transmission, to thereby prevent the occurrence of noise in the monocrystalline silicon diaphragm above the recess.

In the device of the capacitive electromechanical transducer manufactured in Example 3, the difference in amount of deformation under atmospheric pressure between the diaphragm of the cell at the outermost periphery and the diaphragm of the cell at the center portion is about 1 nm. On the other hand, the device having no groove has the above-mentioned difference in amount of deformation of about 40 nm under atmospheric pressure. With the above-mentioned groove formed, the fluctuations in diaphragm deformation amount can be reduced and the fluctuations in detection sensitivity and transmission efficiency can be reduced significantly. Also the transducer manufactured in Example 3 has the insulating film at the bottom surface of the groove. In the configuration in which the monocrystalline silicon film above the groove is removed, the insulating film prevents the exposure of the first silicon substrate 1, thereby preventing short-circuit between the electrode 11 and the first silicon substrate 1, which is otherwise caused when an external conductive substance is adhered between the upper electrode 11 and the groove.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-027966, filed Feb. 11, 2011, which is hereby incorporated by reference herein in its entirety.

1. A method of manufacturing a capacitive electromechanical transducer, comprising:
forming an insulating layer on a first silicon substrate, and forming at least one recess in the insulating layer;
fusion bonding a second silicon substrate onto the insulating layer; and
thinning the second silicon substrate, and forming a silicon film,
the method further comprising, before the fusion bonding of the second silicon substrate onto the insulating layer, forming a groove in the insulating layer at a periphery of the at least one recess.

2. A method of manufacturing a capacitive electromechanical transducer according to claim 1, further comprising electrically separating the at least one recess and the groove.

3. A method of manufacturing a capacitive electromechanical transducer according to claim 1, wherein the forming of the at least one recess and the forming of the groove are performed together in the same step.

4. A method of manufacturing a capacitive electromechanical transducer according to claim 1, further comprising removing the silicon film formed above the groove.

5. A method of manufacturing a capacitive electromechanical transducer according to claim 1, wherein the groove has a starting point and an end point, in which the insulating layer is positioned between the starting point and the end point.

6. A method of manufacturing a capacitive electromechanical transducer according to claim 5, further comprising forming electrical wiring connected to an electrode above the recess, the electrical wiring being formed above the insulating layer between the starting point and the end point of the groove.

7. A method of manufacturing a capacitive electromechanical transducer according to claim 1, wherein the groove comprises a continuous closed loop groove.

8. A method of manufacturing a capacitive electromechanical transducer according to claim 7, further comprising forming electrical wiring connected to an electrode above the recess so as to cross the continuous closed loop groove.

9. A method of manufacturing a capacitive electromechanical transducer according to claim 1, wherein one of the groove and the continuous closed loop groove is formed around the at least one recess so as to enclose the at least one recess multiple times in parallel.
